(19) United States
(12) Patent Application Publication
(10) Pub. No.: US 2017/0062023 A1
(43) Pub. Date: Mar. 2, 2017

(54) SYSTEMS AND METHODS TO REJUVENATE NONVOLATILE MEMORY USING TIMESTAMPS

(71) Applicant: Intel Corporation, Santa Clara, CA (US)

(72) Inventors: Shamanna M. Datta, Hillsboro, OR (US); Richard P. Mangold, Forest Grove, OR (US); Mahesh S. Natu, Sunnyvale, CA (US)

(73) Assignee: INTEL CORPORATION, Santa Clara, CA (US)

(21) Appl. No.: 14/836,923

(22) Filed: Aug. 26, 2015

(51) Int. Cl. G11C 5/14

(52) U.S. Cl. CPC G11C 5/148

(57) ABSTRACT

Apparatus, systems, and methods to implement boot operations in nonvolatile storage devices can include, in one example, a controller comprising logic to receive a power down instruction, record a timestamp associated with the power down instruction, and store the timestamp in a nonvolatile memory table communicatively coupled to the controller. Other examples are also disclosed and claimed.

### FIELD

The present disclosure generally relates to the field of electronics. More particularly, aspects generally relate to systems and methods to rejuvenate nonvolatile memory.

### BACKGROUND

Data stored in nonvolatile memory such as nonvolatile direct in-line memory modules (NV-DIMMs) and nonvolatile solid state drives (SSDs) degrades over time. If such nonvolatile memory devices are stored for sufficiently long periods of time without refresh operations being applied to the memory then data stored in the memory may degrade to the point where such data is no longer accessible. Accordingly, techniques to rejuvenate nonvolatile memory may find utility, e.g., in memory systems for electronic devices.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 is a schematic, block diagram illustration of components of an apparatus in which operations to rejuvenate nonvolatile memory may be implemented in accordance with various examples discussed herein.

FIG. 2 is a schematic, block diagram illustration of operations in a method to rejuvenate nonvolatile memory that may be implemented in accordance with various examples discussed herein.

FIG. 3 is a schematic illustration of an operating environment in which operations to rejuvenate nonvolatile memory may be implemented in accordance with various examples discussed herein.

FIGS. 4-5 are schematic, block diagram illustrations of operations in a method to rejuvenate nonvolatile memory that may be implemented in accordance with various examples discussed herein.

FIGS. 6-10 are schematic, block diagram illustrations of electronic devices which may be adapted to implement boot operations in storage devices may be implemented in accordance with various examples discussed herein.

### DETAILED DESCRIPTION

In the following description, numerous specific details are set forth in order to provide a thorough understanding of various examples. However, various examples may be practiced without the specific details. In other instances, well-known methods, procedures, components, and circuits have not been described in detail so as not to obscure the particular examples. Further, various aspects of examples may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

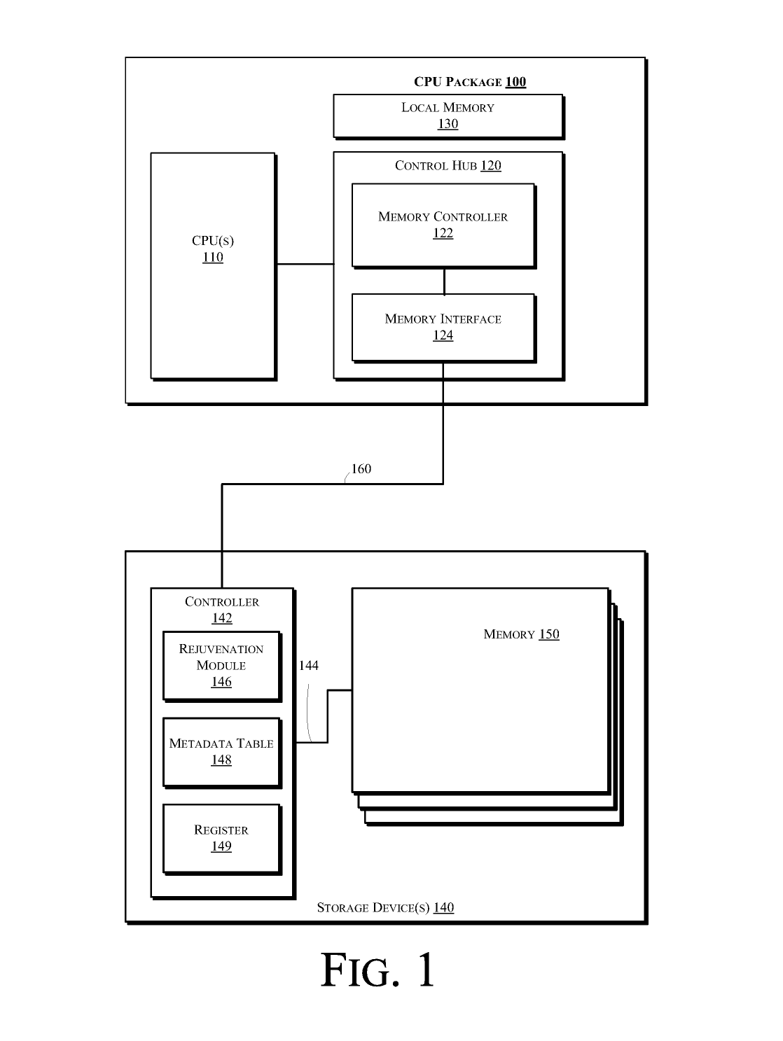

Techniques to rejuvenate nonvolatile memory of a storage device, such as an NV-DIMM or SSD, are described in detail below. In brief, during a power down sequence a controller coupled to a storage device may record a timestamp associated with the power down operation in a nonvolatile memory. In a subsequent rejuvenation process the controller may retrieve a rejuvenation policy from a remote device, read the timestamp from a metadata table in nonvolatile memory, and determine whether to implement a rejuvenation operation based at least in part on the timestamp and the rejuvenation policy. In some examples multiple copies of metadata table may be maintained to protect the timestamp from data degradation. Specific details of a systems and methods to manage read devices in electronic devices will be described below with reference to FIGS. 1-10.

FIG. 1 is a schematic, block diagram illustration of components of an apparatus in which operations to rejuvenate nonvolatile memory may be implemented in accordance with various examples discussed herein. Referring to FIG. 1, in some examples a central processing unit (CPU) package 100 which may comprise one or more CPUs 110 coupled to a control hub 120 and a local memory 130. Control hub 120 comprises a memory controller 122 and a memory interface 124. In some examples the control hub 120 may be integrated with the processor(s) 110.

Memory interface 124 is coupled to one or more remote storage devices 140 by a communication bus 160. Storage device 140 may be implemented as a solid state drive (SSD), a nonvolatile direct in-line memory module (NV-DIMM) or the like and comprise a controller 142 and memory 150. In various examples, at least some of the memory 150 may comprise nonvolatile memory, e.g., phase change memory, NAND (flash) memory, ferroelectric random-access memory (FeTRAM), nanowire-based non-volatile memory, memory that incorporates memristor technology, a static random access memory (SRAM), three dimensional cross-point memory, spin-transfer torque memory (STT-RAM) or NAND memory. The specific configuration of the memory 150 in the storage device(s) 140 is not critical. In such embodiments the memory interface may comprise an interface compatible with the Serial Advanced Technology Attachment (SATA) specification(s) publicly accessible on the SATA website at www.serialata.org, a PCI Express (PCIE) interface publicly accessible at http://pcisig.com/specifications/pciexpress/, a nonvolatile media express (NVMe) interface publicly available at www.nymexpress.org, or the like.

Controller 142 may comprise logic, at least partially including hardware logic, defining a rejuvenation module 146. Further, controller 142 may maintain a metadata table 148 to store metadata for the memory 150. In some examples, controller 142 may further comprise a register 149, the contents of which may be made accessible to the test device 300. In further examples the metadata table 148 may be stored in the memory 150.

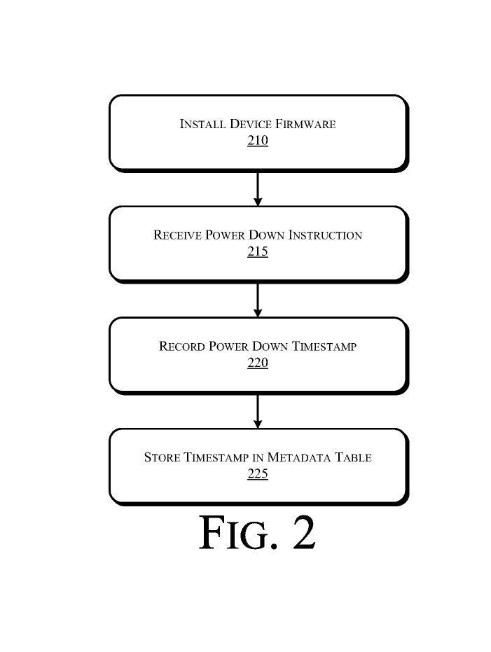

FIG. 2 is a schematic, block diagram illustration of operations in a method to rejuvenate nonvolatile memory that may be implemented in accordance with various examples discussed herein. Referring to FIG. 2, in some examples a manufacturer or distributor of a storage device 150 may install device firmware (operation 210) on the controller 142. At operation 215 the controller 142 may receive a power down instruction, and at operation 220 the controller 142 may record a timestamp associated with the power down operation. At operation 225 the timestamp may be stored in metadata table 148.

Storage device 150 may then be shipped in commerce during which time it may be held in one or more warehouses, retail outlets, or other facilities in power down state and therefore susceptible to data degradation, as discussed above. In order to determine whether the memory 150 in storage device 140 should be subjected to a rejuvenation process the storage device 140 may be coupled to a test device 300, which may cooperate with the controller 142 on the storage device 140 to execute a test routine on the memory 150.

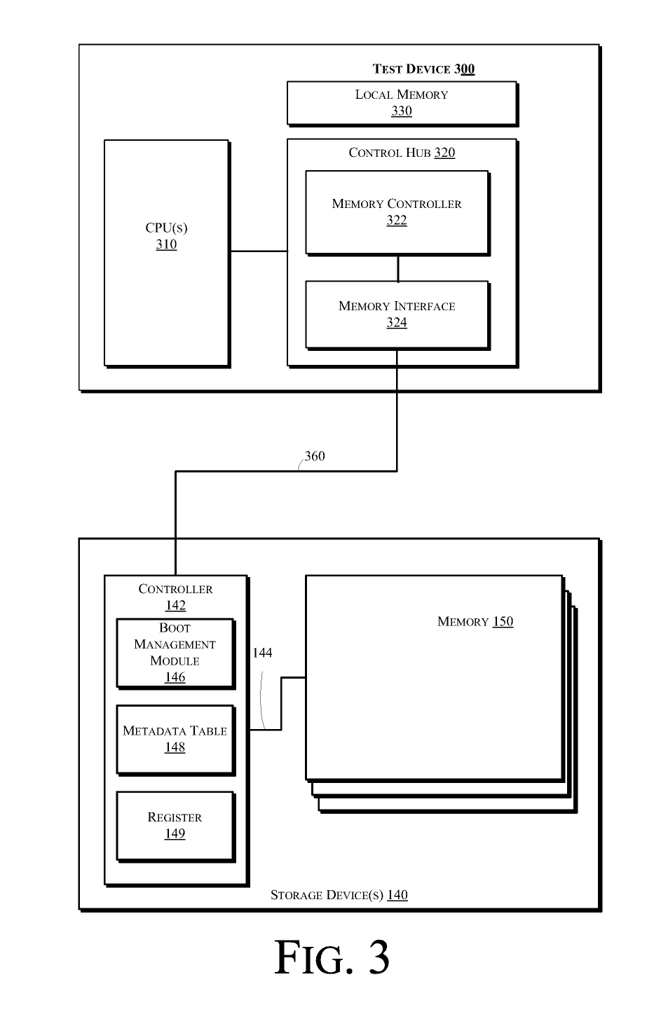

FIG. 3 is a schematic illustration of an operating environment in which operations to rejuvenate nonvolatile memory may be implemented in accordance with various examples discussed herein. In some embodiments test device 300 may be embodied as a computing device which includes one or more central processing units CPUs 110 coupled to a control hub 320 and a local memory 330. Control hub 120 comprises a memory controller 322 and a memory interface 324. In some examples the control hub 320 may be integrated with the processor(s) 310. Memory interface 324 may be coupled to one or more remote storage devices 140 by a communication bus 360.

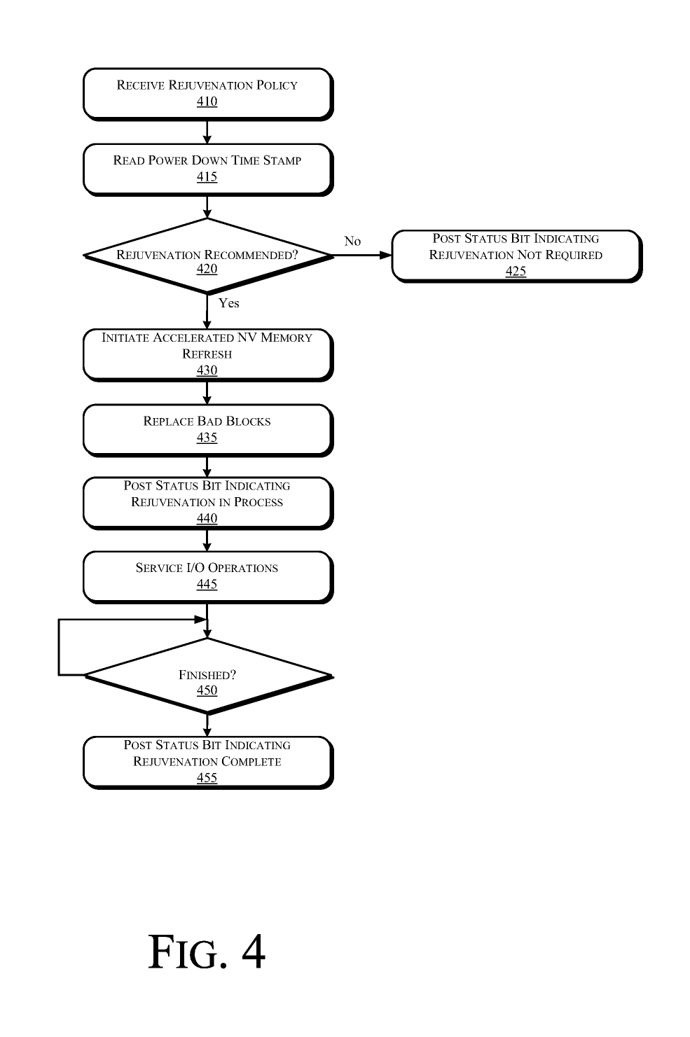

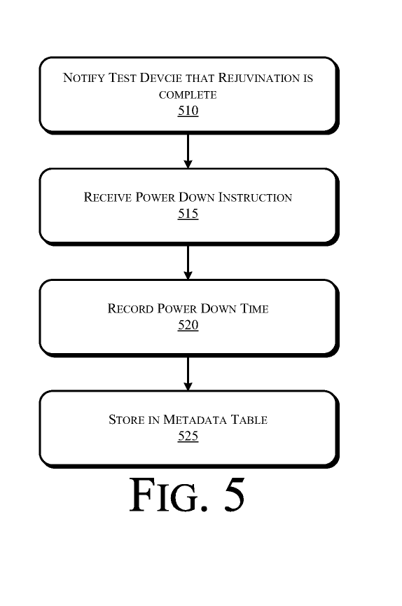

Operations implemented by controller 142 in a method to rejuvenate nonvolatile memory will be described with reference to FIGS. 4-5. Referring to FIG. 4, at operation 410 the controller 142 receives from the test device 300 one or more portions of a rejuvenation policy for the storage device 140. In some examples the rejuvenation policy may be established by the manufacturer or distributor of the storage device 150 and may include one or more rules which suggest when rejuvenation of the memory 150 is recommended. In one example a rejuvenation policy may recommend rejuvenation of the memory after the elapse of a predetermined time period from the power down instruction received in operation 215. The time period may be adjusted based on environmental conditions in which the storage device 150 is stored.

At operation 415 the controller 142 reads the time stamp associated with the power down instruction received in operation 215, and at operation 420 the controller 142 determines whether rejuvenation is recommended. In some examples the controller 142 recommends rejuvenation if an amount of time greater than the predetermined time period from the power down instruction received in operation 215 has elapsed. If, at operation 420, rejuvenation is not recommended then control passes to operation 425 and the controller 142 posts a status bit to register 149 indicating that rejuvenation is not required. In some examples the test device 300 may read the status bit and present a visual and/or audible indication via a user interface that rejuvenation is not required.

By contrast, if, at operation 420, rejuvenation is recommended then control passes to operation 430 and the controller 142 initiates an accelerated refresh operation on the nonvolatile memory 150 of storage device 140. In some examples as part of the accelerated refresh operation the controller 142 may reduce at least one operating parameter of the storage device 140. For example, controller may reduce other input/output (I/O) operations directed to the memory 150 of storage device 140 during the accelerated refresh operation. As part of the refresh operation any bad blocks in memory 150 (i.e., blocks of memory which generate read or write errors) may be replaced (operation 440) with good blocks of memory (i.e., memory which does not generate read or write errors). For example, blocks of memory which generate read or write errors may be marked as unusable such that read or write operations are directed to other blocks of memory which do not generate read or write errors. At operation 445 the controller 142 may start to service other I/O operations directed to the memory 150 of storage device 140, albeit at a reduced rate.

At operation 450 the controller 142 determines whether the rejuvenation process is finished. In some examples the rejuvenation process continues until all memory locations in the memory 150 of storage device 140 have been refreshed. If, at operation 450, the rejuvenation process is not finished then the controller continues refresh operations. By contrast, if at operation 450 the rejuvenation operation is finished then control passes to operation 455 and the controller posts a status bit to register 149 indicating that rejuvenation is complete. In some examples the test device 300 may read the status bit and present a visual and/or audible indication via a user interface that rejuvenation is complete.

Referring to FIG. 5, once the rejuvenation process is complete the controller 142 may notify test device 300 that the rejuvenation process is complete. At operation 515 the controller 142 may receive a power down instruction from the test device, and at operation 520 the controller 142 may record a timestamp associated with the power down operation. At operation 525 the timestamp may be stored in metadata table 148, thereby providing an updated timestamp for the memory 150 of storage device 140.

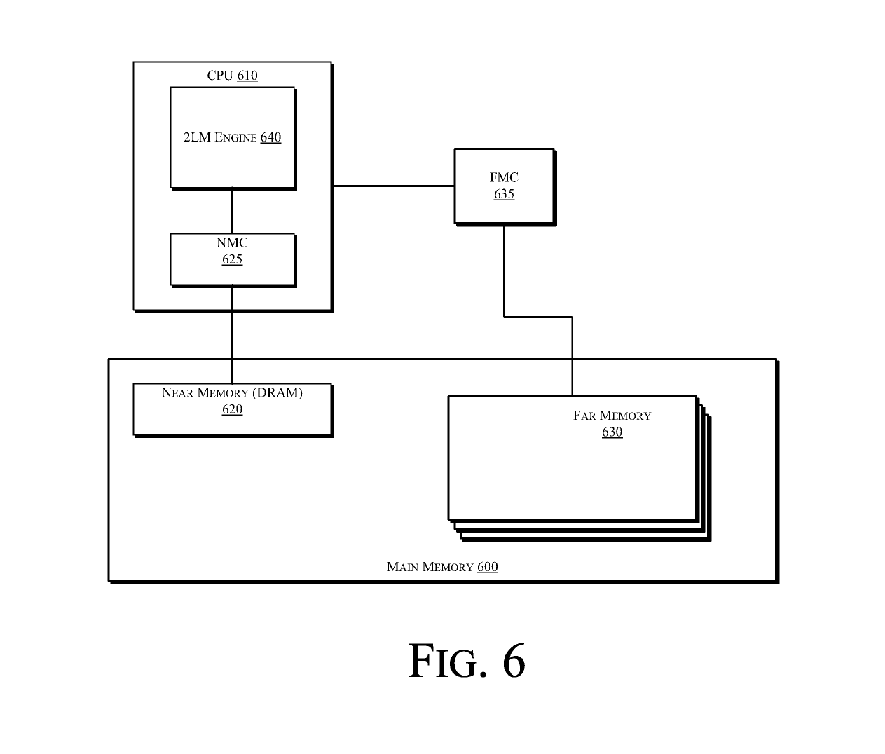

As described above, in some examples the electronic device may be embodied as a computer system. FIG. 6 is a schematic, block diagram illustration of a system that includes a memory module in accordance with various examples discussed herein.. Referring to FIG. 6, system main memory 600 provides run-time data storage and access to the contents of system disk storage memory (not shown) to CPU 610. CPU 610 may include cache memory, which would store a subset of the contents of main memory 600.

In this embodiment there are two levels of memory. Main memory 600 includes a level of volatile memory shown as near memory (DRAM) 620, and a level of memory, shown as far memory 630. Far memory may comprise either volatile memory, e.g., static random access memory (SRAM), a dynamic random access memory (DRAM), nonvolatile memory, or may include nonvolatile memory e.g., phase change memory, NAND (flash) memory, ferroelectric random-access memory (FeRAM), nanowire-based non-volatile memory, memory that incorporates memristor technology, three dimensional (3D) cross point memory, magnetoresistive random access memory (MRAM), spin-transfer torque memory (STT-RAM) or NAND flash memory. In this embodiment, near memory 620 serves a low-latency and high-bandwidth (i.e., for CPU 610 access) cache of far memory 630, which may have considerably lower bandwidth and higher latency (i.e., for CPU 610 access).

In this embodiment, near memory 620 is managed by near memory controller (NMC) 625, while far memory 630 is managed by far memory controller (FMC) 635. FMC 635 reports far memory 630 to the system operating system (OS) as main memory—i.e., the system OS recognizes the size of far memory 630 as the size of system main memory 600. The system OS and system applications are “unaware” of the existence of near memory 620 as it is a “transparent” cache of far memory 630.

CPU 610 further comprises a two-level memory (2LM) engine module/logic 640. The “2LM engine” is a logical construct that may comprise hardware and/or micro-code extensions to support two-level main memory 600. For example, 2LM engine 640 may maintain a full tag table that tracks the status of all architecturally visible elements of far memory 630. For example, when CPU 610 attempts to access a specific data segment in main memory 600, 2LM engine 640 determines whether said data segment is included in near memory 620; if it is not, 2LM engine 640 fetches the data segment in far memory 630 and subsequently writes the data segment to near memory 620 (similar to a cache miss). It is to be understood that, because near memory 620 acts as a “cache” of far memory 630, 2LM engine 140 may further execute data prefetching or similar cache efficiency processes known in the art.

The 2LM engine 640 may manage other aspects of far memory 630. For example, in embodiments where far memory 630 comprises nonvolatile memory, it is understood that nonvolatile memory such as flash is subject to degradation of memory segments due to significant reads/writes. Thus, 2LM engine 640 may execute functions including wear-leveling, bad-block avoidance, and the like in a manner transparent to system software. For example, executing wear-leveling logic may include selecting segments from a free pool of clean unmapped segments in far memory 630 that have a relatively low erase cycle count.

It is to be understood that near memory 620 is smaller in size than far memory 630, although the exact ratio may vary based on, for example, intended system use. In this embodiment, it is to be understood that because far memory 630 comprises denser, cheaper nonvolatile memory, main memory 600 may be increased cheaply and efficiently and independent of the amount of DRAM (i.e., near memory 620) in the system.

In various embodiments, at least some of the memory in memory devices 650 may be configured as DIMM devices and may include non-volatile memory, e.g., phase change memory (PCM), a three dimensional cross point memory, a resistive memory, nanowire memory, ferro-electric transistor random access memory (FeTRAM), flash memory such as NAND or NOR, magnetoresistive random access memory (MRAM) memory that incorporates memristor technology, spin transfer torque (STT)-MRAM.

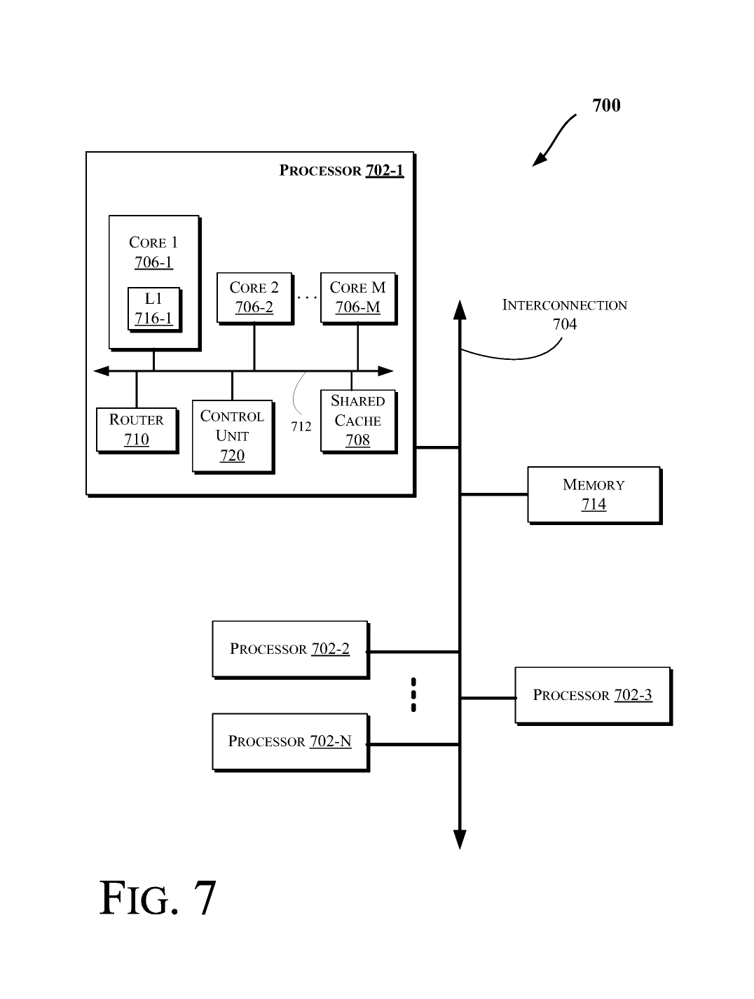

FIG. 7 illustrates a block diagram of a computing system 700, according to an example. The system 700 may include one or more processors 702-1 through 702-N (generally referred to herein as “processors 702” or “processor 702”). The processors 702 may communicate via an interconnection network or bus 704. Each processor may include various components some of which are only discussed with reference to processor 702-1 for clarity. Accordingly, each of the remaining processors 702-2 through 702-N may include the same or similar components discussed with reference to the processor 702-1.

In an example, the processor 702-1 may include one or more processor cores 706-1 through 706-M (referred to herein as “cores 706” or more generally as “core 706”), a shared cache 708, a router 710, and/or a processor control logic or unit 720. The processor cores 706 may be implemented on a single integrated circuit (IC) chip. Moreover, the chip may include one or more shared and/or private caches (such as cache 708), buses or interconnections (such as a bus or interconnection network 712), memory controllers, or other components.

In one example, the router 710 may be used to communicate between various components of the processor 702-1 and/or system 700. Moreover, the processor 702-1 may include more than one router 710. Furthermore, the multitude of routers 710 may be in communication to enable data routing between various components inside or outside of the processor 702-1.

The shared cache 708 may store data (e.g., including instructions) that are utilized by one or more components of the processor 702-1, such as the cores 706. For example, the shared cache 708 may locally cache data stored in a memory 714 for faster access by components of the processor 702. In an example, the cache 708 may include a mid-level cache (such as a level 2 (L2), a level 3 (L3), a level 4 (L4), or other levels of cache), a last level cache (LLC), and/or combinations thereof. Moreover, various components of the processor 702-1 may communicate with the shared cache 708 directly, through a bus (e.g., the bus 712), and/or a memory controller or hub. As shown in FIG. 7, in some examples, one or more of the cores 706 may include a level 1 (L1) cache 716-1 (generally referred to herein as “L1 cache 716”).

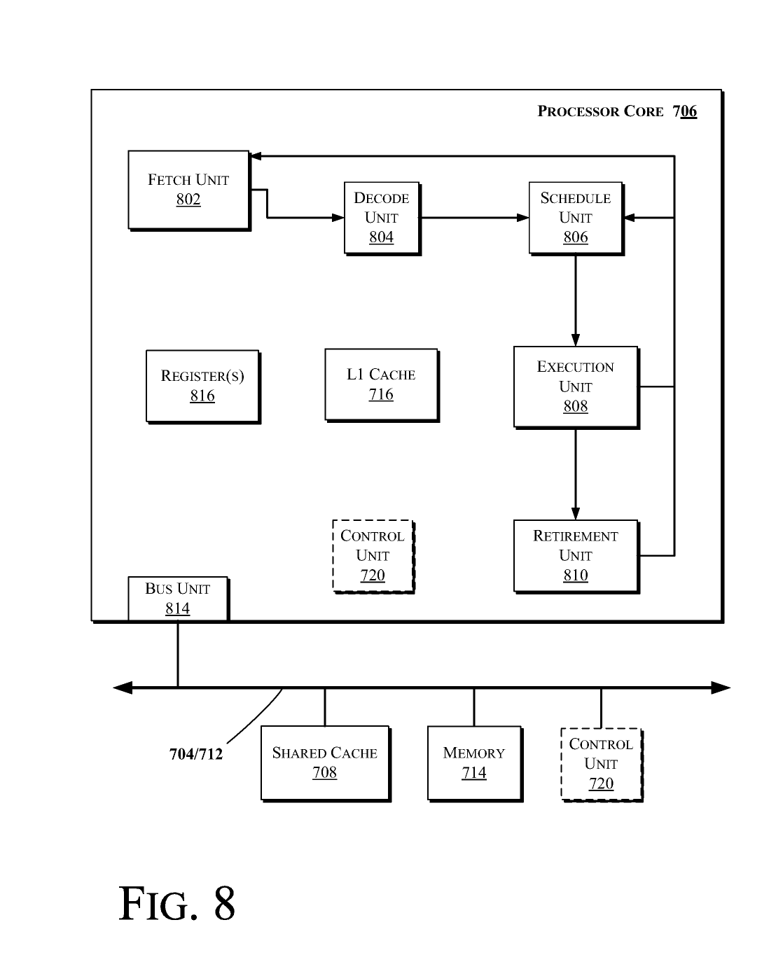

FIG. 8 illustrates a block diagram of portions of a processor core 706 and other components of a computing system, according to an example. In one example, the arrows shown in FIG. 8 illustrate the flow direction of instructions through the core 706. One or more processor cores (such as the processor core 706) may be implemented on a single integrated circuit chip (or die) such as discussed with reference to FIG. 7. Moreover, the chip may include one or more shared and/or private caches (e.g., cache 708 of FIG. 7), interconnections (e.g., interconnections 704 and/or 112 of FIG. 7), control units, memory controllers, or other components.

As illustrated in FIG. 8, the processor core 706 may include a fetch unit 802 to fetch instructions (including instructions with conditional branches) for execution by the core 706. The instructions may be fetched from any storage devices such as the memory 714. The core 706 may also include a decode unit 804 to decode the fetched instruction. For instance, the decode unit 804 may decode the fetched instruction into a plurality of uops (micro-operations).

Additionally, the core 706 may include a schedule unit 806. The schedule unit 806 may perform various operations associated with storing decoded instructions (e.g., received from the decode unit 804) until the instructions are ready for dispatch, e.g., until all source values of a decoded instruction become available. In one example, the schedule unit 806 may schedule and/or issue (or dispatch) decoded instructions to an execution unit 808 for execution. The execution unit 808 may execute the dispatched instructions after they are decoded (e.g., by the decode unit 804) and dispatched (e.g., by the schedule unit 806). In an example, the execution unit 808 may include more than one execution unit. The execution unit 808 may also perform various arithmetic operations such as addition, subtraction, multiplication, and/or division, and may include one or more an arithmetic logic units (ALUs). In an example, a co-processor (not shown) may perform various arithmetic operations in conjunction with the execution unit 808.

Further, the execution unit 808 may execute instructions out-of-order. Hence, the processor core 706 may be an out-of-order processor core in one example. The core 706 may also include a retirement unit 810. The retirement unit 810 may retire executed instructions after they are committed. In an example, retirement of the executed instructions may result in processor state being committed from the execution of the instructions, physical registers used by the instructions being de-allocated, etc.

The core 706 may also include a bus unit 714 to enable communication between components of the processor core 706 and other components (such as the components discussed with reference to FIG. 8) via one or more buses (e.g., buses 804 and/or 812). The core 706 may also include one or more registers 816 to store data accessed by various components of the core 706 (such as values related to power consumption state settings).

Furthermore, even though FIG. 7 illustrates the control unit 720 to be coupled to the core 706 via interconnect 812, in various examples the control unit 720 may be located elsewhere such as inside the core 706, coupled to the core via bus 704, etc.

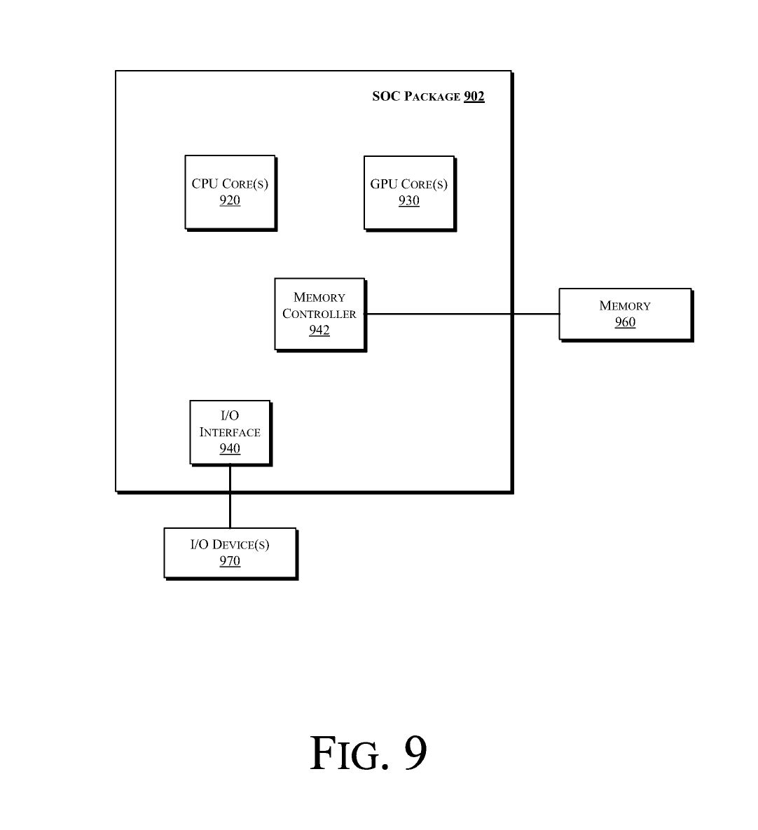

In some examples, one or more of the components discussed herein can be embodied as a System On Chip (SOC) device. FIG. 9 illustrates a block diagram of an SOC package in accordance with an example. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 902 may include one or more other components, e.g., as discussed with reference to the other figures herein. In one example, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an example, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch screen, a speaker, or the like.

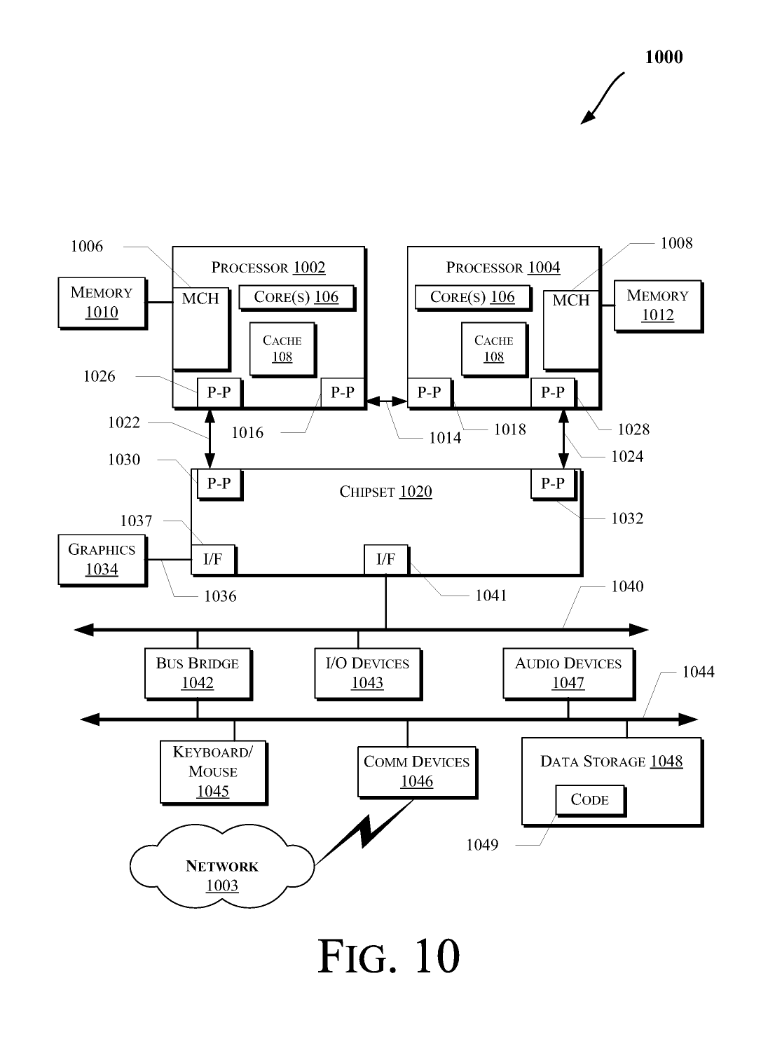

FIG. 10 illustrates a computing system 1000 that is arranged in a point-to-point (PtP) configuration, according to an example. In particular, FIG. 10 shows a system where processors, memory, and input/output devices are interconnected by a number of point-to-point interfaces.

As illustrated in FIG. 10, the system 1000 may include several processors, of which only two, processors 1002 and 1004 are shown for clarity. The processors 1002 and 1004 may each include a local memory controller hub (MCH) 1006 and 1008 to enable communication with memories 1010 and 1012.

In an example, the processors 1002 and 1004 may be one of the processors 702 discussed with reference to FIG. 7. The processors 1002 and 1004 may exchange data via a point-to-point (PtP) interface 1014 using PtP interface circuits 1016 and 1018, respectively. Also, the processors 1002 and 1004 may each exchange data with a chipset 1020 via individual PtP interfaces 1022 and 1024 using point-to-point interface circuits 1026, 1028, 1030, and 1032. The chipset 1020 may further exchange data with a high-performance graphics circuit 1034 via a high-performance graphics interface 1036, e.g., using a PtP interface circuit 1037.

The chipset 1020 may communicate with a bus 1040 using a point-to-point PtP interface circuit 1041. The bus 1040 may have one or more devices that communicate with it, such as a bus bridge 1042 and I/O devices 1043. Via a bus 1044, the bus bridge 1043 may communicate with other devices such as a keyboard/mouse 1045, communication devices 1046 (such as modems, network interface devices, or other communication devices that may communicate with the computer network 803), audio I/O device, and/or a data storage device 1048. The data storage device 1048 (which may be a hard disk drive or a NAND flash based solid state drive) may store code 1049 that may be executed by the processors 1002 and/or 1004.

The following pertains to further examples.

Example 1 is an electronic device comprising at least one processor, at least one memory device comprising a nonvolatile memory, and a controller coupled to the memory and comprising logic, at least partially including hardware logic, to receive a power down instruction, record a timestamp associated with the power down instruction, and store the timestamp in a metadata table communicatively coupled to the controller.

In Example 2, the subject matter of Example 1 can optionally include logic, at least partially including hardware logic, to retrieve a rejuvenation policy from a remote device, read the timestamp from the metadata table in nonvolatile memory, and determine whether to implement a rejuvenation operation based at least in part on the timestamp and the rejuvenation policy.

In Example 3, the subject matter of any one of Examples 1-2 can optionally include logic, at least partially including hardware logic, to set a status bit in a control register accessible to a remote device to a first value in response to a determination not to implement a rejuvenation operation.

In Example 4, the subject matter of any one of Examples 1-3 can optionally include logic, at least partially including hardware logic, to set a status bit in a control register accessible to a remote device to a second value in response to a determination to implement a rejuvenation operation.

In Example 5, the subject matter of any one of Examples 1-4 can optionally include logic, at least partially including hardware logic, to implement an accelerated refresh operation on the nonvolatile memory in response to a determination to implement a rejuvenation operation.

In Example 6, the subject matter of any one of Examples 1-5 can optionally include logic, at least partially including hardware logic, to reduce at least one operating parameter of the storage device in response to a determination to implement a rejuvenation operation.

In Example 7, the subject matter of any one of Examples 1-6 can optionally include logic, at least partially including hardware logic, to set a status bit in a control register accessible to a remote device to a third value in response to a completion of the rejuvenation operation.

In Example 8, the subject matter of any one of Examples 1-7 can optionally include logic, at least partially including hardware logic, to restore full operation of the storage device in response to a completion of the rejuvenation operation.

Example 9 is a storage device comprising a nonvolatile memory, and a controller coupled to the memory and comprising logic, at least partially including hardware logic, to receive a power down instruction, record a timestamp associated with the power down instruction, and store the timestamp in a metadata table communicatively coupled to the controller.

In Example 10, the subject matter of Example 9 can optionally include logic, at least partially including hardware logic, to retrieve a rejuvenation policy from a remote device, read the timestamp from the metadata table in nonvolatile memory, and determine whether to implement a rejuvenation operation based at least in part on the timestamp and the rejuvenation policy.

In Example 11, the subject matter of any one of Examples 9-10 can optionally include logic, at least partially including hardware logic, to set a status bit in a control register accessible to a remote device to a first value in response to a determination not to implement a rejuvenation operation.

In Example 12, the subject matter of any one of Examples 9-11 can optionally include logic, at least partially including hardware logic, to set a status bit in a control register accessible to a remote device to a second value in response to a determination to implement a rejuvenation operation.

In Example 13, the subject matter of any one of Examples 9-12 can optionally include logic, at least partially including hardware logic, to implement an accelerated refresh operation on the nonvolatile memory in response to a determination to implement a rejuvenation operation.

In Example 14, the subject matter of any one of Examples 9-13 can optionally include logic, at least partially including hardware logic, to reduce at least one operating parameter of the storage device in response to a determination to implement a rejuvenation operation.

In Example 15, the subject matter of any one of Examples 9-14 can optionally include logic, at least partially including hardware logic, to set a status bit in a control register accessible to a remote device to a third value in response to a completion of the rejuvenation operation.

In Example 16, the subject matter of any one of Examples 9-15 can optionally include logic, at least partially including hardware logic, to restore full operation of the storage device in response to a completion of the rejuvenation operation.

Example 17 is a controller comprising logic, at least partially including hardware logic, to receive a power down instruction, record a timestamp associated with the power down instruction, and store the timestamp in a metadata table communicatively coupled to the controller.

In Example 18, the subject matter of Example 17 can optionally include logic, at least partially including hardware logic, to retrieve a rejuvenation policy from a remote device, read the timestamp from the metadata table in nonvolatile memory, and determine whether to implement a rejuvenation operation based at least in part on the timestamp and the rejuvenation policy.

In Example 19, the subject matter of any one of Examples 17-18 can optionally include logic, at least partially including hardware logic, to set a status bit in a control register accessible to a remote device to a first value in response to a determination not to implement a rejuvenation operation.

In Example 20, the subject matter of any one of Examples 17-19 can optionally include logic, at least partially including hardware logic, to set a status bit in a control register accessible to a remote device to a second value in response to a determination to implement a rejuvenation operation.

In Example 21, the subject matter of any one of Examples 17-20 can optionally include logic, at least partially including hardware logic, to implement an accelerated refresh operation on the nonvolatile memory in response to a determination to implement a rejuvenation operation.

In Example 22, the subject matter of any one of Examples 17-21 can optionally include logic, at least partially including hardware logic, to reduce at least one operating parameter of the storage device in response to a determination to implement a rejuvenation operation.

In Example 23, the subject matter of any one of Examples 17-22 can optionally include logic, at least partially including hardware logic, to set a status bit in a control register accessible to a remote device to a third value in response to a completion of the rejuvenation operation.

In Example 24, the subject matter of any one of Examples 17-23 can optionally include logic, at least partially including hardware logic, to restore full operation of the storage device in response to a completion of the rejuvenation operation.

In various examples, the operations discussed herein, e.g., with reference to FIGS. 1-10, may be implemented as hardware (e.g., circuitry), software, firmware, microcode, or combinations thereof, which may be provided as a computer program product, e.g., including a tangible (e.g., non-transitory) machine-readable or computer-readable medium having stored thereon instructions (or software procedures) used to program a computer to perform a process discussed herein. Also, the term “logic” may include, by way of example, software, hardware, or combinations of software and hardware. The machine-readable medium may include a storage device such as those discussed herein.

Reference in the specification to “one example” or “an example” means that a particular feature, structure, or characteristic described in connection with the example may be included in at least an implementation. The appearances of the phrase “in one example” in various places in the specification may or may not be all referring to the same example.

Also, in the description and claims, the terms “coupled” and “connected,” along with their derivatives, may be used. In some examples, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although examples have been described in language specific to structural features and/or methodological acts, it is to be understood that claimed subject matter may not be limited to the specific features or acts described. Rather, the specific features and acts are disclosed as sample forms of implementing the claimed subject matter.

1. An electronic device, comprising:
at least one processor; and
at least one storage device comprising:
a nonvolatile memory; and
a controller coupled to the at least one storage device and comprising logic, at least partially including hardware logic, to:
receive a power down instruction;
record a timestamp associated with the power down instruction; and
store the timestamp in a metadata table communicatively coupled to the controller;
retrieve a rejuvenation policy from a remote device;
read the timestamp from the metadata table communicatively coupled to the controller;
determine whether to implement a rejuvenation operation based, at least in part, on the timestamp and the rejuvenation policy;
set a status bit in a control register accessible to the remote device to a first value in response to a determination not to implement the rejuvenation operation; and
set a status bit in the control register accessible to the remote device to a second value in response to a determination to implement the rejuvenation operation.

2-4. (canceled)

5. The electronic device of claim 1, wherein the controller comprises logic, at least partially including hardware logic, to:
implement an accelerated refresh operation on the nonvolatile memory in response to a determination to implement the rejuvenation operation.

6. The electronic device of claim 5, wherein the controller comprises logic, at least partially including hardware logic, to:
reduce at least one operating parameter of the storage device in response to the determination to implement the rejuvenation operation.

7. The electronic device of claim 5, wherein the controller comprises logic, at least partially including hardware logic, to:
set a status bit in the control register accessible to the remote device to a third value in response to a completion of the rejuvenation operation.

8. The electronic device of claim 5, wherein the controller comprises logic, at least partially including hardware logic, to:
restore full operation of the storage device in response to a completion of the rejuvenation operation.

9. A storage device, comprising:
a nonvolatile memory; and
a controller coupled to the nonvolatile memory and comprising logic, at least partially including hardware logic, to:
receive a power down instruction;
record a timestamp associated with the power down instruction; and
store the timestamp in a metadata table communicatively coupled to the controller;
retrieve a rejuvenation policy from a remote device;
read the timestamp from the metadata table communicatively coupled to the controller;
determine whether to implement a rejuvenation operation based, at least in part, on the timestamp and the rejuvenation policy;
set a status bit in a control register accessible to the remote device to a first value in response to a determination not to implement the rejuvenation operation; and
set a status bit in the control register accessible to the remote device to a second value in response to a determination to implement the rejuvenation operation.

10-12. (canceled)

13. The storage device of claim 9, wherein the controller comprises logic, at least partially including hardware logic, to:
implement an accelerated refresh operation on the nonvolatile memory in response to a determination to implement the rejuvenation operation.

14. The storage device of claim 13, wherein the controller comprises logic, at least partially including hardware logic, to:
reduce at least one operating parameter of the storage device in response to the determination to implement the rejuvenation operation.

15. The storage device of claim 13, wherein the controller comprises logic, at least partially including hardware logic, to:
set a status bit in the control register accessible to the remote device to a third value in response to a completion of the rejuvenation operation.

16. The storage device of claim 13, wherein the controller comprises logic, at least partially including hardware logic, to:
restore full operation of the storage device in response to a completion of the rejuvenation operation.

17. A controller comprising logic, at least partially including hardware logic, to:
receive a power down instruction;
record a timestamp associated with the power down instruction;
store the timestamp in a metadata table communicatively coupled to the controller;
retrieve a rejuvenation policy from a remote device;
read the timestamp from the metadata table communicatively coupled to the controller;
determine whether to implement a rejuvenation operation based, at least in part, on the timestamp and the rejuvenation policy;
set a status bit in a control register accessible to the remote device to a first value in response to a determination not to implement the rejuvenation operation; and
set a status bit in the control register accessible to the remote device to a second value in response to a determination to implement the rejuvenation operation.

18-20. (canceled)

21. The controller of claim 17, wherein the controller comprises logic, at least partially including hardware logic, to:
implement an accelerated refresh operation on the nonvolatile memory in response to a determination to implement the rejuvenation operation.

22. The controller of claim 21, wherein the controller comprises logic, at least partially including hardware logic, to:
reduce at least one operating parameter of the storage device in response to the determination to implement the rejuvenation operation.

23. The controller of claim 21, wherein the controller comprises logic, at least partially including hardware logic, to:
set a status bit in the control register accessible to the remote device to a third value in response to a completion of the rejuvenation operation.

24. The controller of claim 21, wherein the controller comprises logic, at least partially including hardware logic, to:
restore full operation of the storage device in response to a completion of the rejuvenation operation.
